(19) United States
(12) Patent Application Publication
(10) Pub. No.: US 2025/0226342 A1
(43) Pub. Date: Jul. 10, 2025

(54) SEMICONDUCTOR STRUCTURE AND METHOD OF MAKING

(71) Applicant: Taiwan Semiconductor Manufacturing Company Limited, Hsin-Chu (TW)

(72) Inventors: Hsi-Cheng HSU, Taichung City (TW); Jui-Chun WENG, Taipei City (TW); Ji-Hong CHIANG, Changhua City (TW); Kuo-Hao LEE, Hsinchu (TW)

(21) Appl. No.: 18/407,946

(22) Filed: Jan. 9, 2024

(51) Int. Cl. H01L 23/00; H01L 23/532

(52) U.S. Cl. CPC H01L 24/08; H01L 23/53228; H01L 24/03; H01L 24/05; H01L 24/09; H01L 24/11; H01L 24/13; H01L 24/16; H01L 2224/03848; H01L 2224/056; H01L 2224/08113; H01L 2224/08245; H01L 2224/0903; H01L 2224/11848; H01L 2224/131; H01L 2224/16113; H01L 2924/1461

(57) ABSTRACT

In some embodiments, a method for forming a semiconductor structure is provided. The method includes forming a first semiconductor layer including a stand-off feature. A bond pad layer is formed over the first semiconductor layer and the stand-off feature. The bond pad layer is patterned to form a first bond pad over the stand-off feature and a second pad over a portion of the first semiconductor layer. An annealing process is performed to increase a surface roughness of the first bond pad and the second pad. The first semiconductor layer is patterned to form a micro-electromechanical systems (MEMS) structure including a movable element. A device die is bonded to the stand-off feature. The second pad is over the movable element.

### BACKGROUND

Micro-electromechanical systems (MEMS) combine mechanical and electronic components on a semiconductor structure. A MEMS structure can be used as a sensor, such as a pressure sensor.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-12 illustrate a semiconductor device at various stages of fabrication, in accordance with some embodiments.

### DETAILED DESCRIPTION

The following disclosure provides several different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals or letters in the various examples. This repetition is for the purpose of simplicity and clarity and does not in itself dictate a relationship between the various embodiments or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation illustrated in the figures. The apparatus may be otherwise oriented (rotated 90 degrees or at other orientations) and the spatially relative descriptors used herein may likewise be interpreted accordingly.

According to some embodiments, a microelectromechanical systems (MEMS) device is formed. The MEMS device is bonded to a device wafer to create a sealed cavity surrounding the MEMS device. Anti-stiction bumps are formed on surfaces of movable elements of the MEMS device. The anti-stiction bumps may be formed from a material layer that is also used for forming a bond pad that bonds the MEMS device to the device wafer. In some embodiments, an annealing process is performed to form the anti-stiction bumps in the bond pad material. The bond pad material may include germanium. Annealing germanium results in the formation of triangular or trapezoidal shaped crystalline structures that form the anti-stiction bumps. The anti-stiction bumps increase the roughness of the surface of the movable elements. If the movement of a movable element in the MEMS device is sufficient to cause the movable element to contact a surface of the device wafer, the anti-stiction bumps reduce the likelihood that the movable element will adhere to the surface of the device wafer and potentially damage the MEMS device. The anti-stiction bumps in the bond pad regions improve the bonding between the MEMS device and the device wafer, thereby relaxing the applied pressure requirements for the bonding process and reducing the likelihood of warping or wafer breakage.

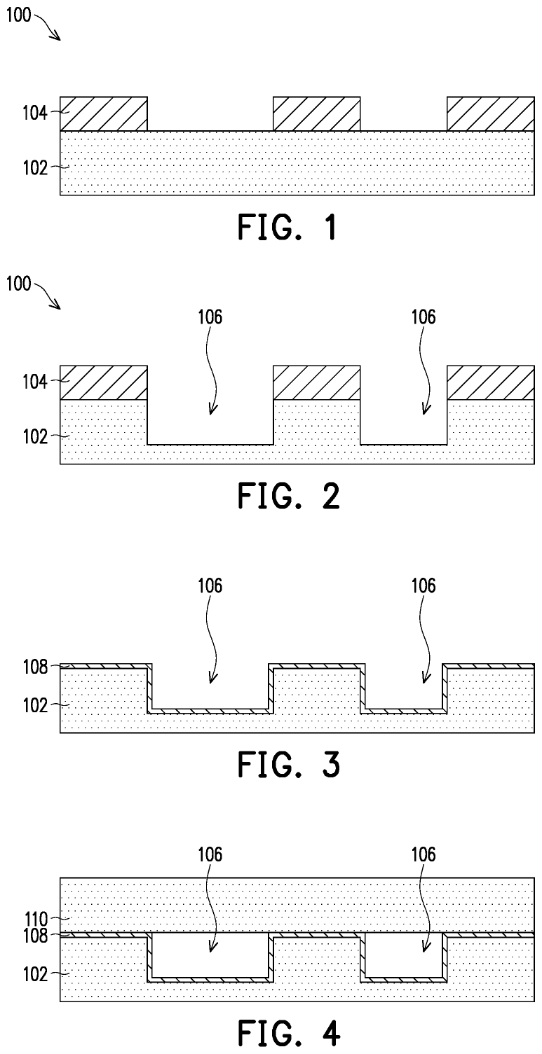

FIGS. 1-12 illustrate a semiconductor structure 100 at various stages of fabrication, in accordance with some embodiments. FIGS. 1-12 illustrate cross-section views of the semiconductor structure 100 at various stages of fabrication. In some embodiments, the semiconductor structure 100 is a MEMS structure. The semiconductor structure 100 includes a semiconductor layer 102 with a patterned mask 104 formed over the semiconductor layer 102. The semiconductor layer 102 comprises at least one of an epitaxial layer, a single crystalline semiconductor material such as, but not limited to at least one of Si, Ge, SiGe, InGaAs, GaAs, InSb, GaP, GaSb, InAlAs, GaSbP, GaAsSb, and InP, a silicon-on-insulator (SOI) structure, a wafer, or a die formed from a wafer. In some embodiments, the semiconductor layer 102 comprises at least one of crystalline silicon or other suitable materials. The semiconductor layer 102 may be a silicon-on-insulator (SOI) substrate comprising a layer of a semiconductor material (e.g., silicon, germanium, or the like) formed over an insulator layer (e.g., buried oxide or the like), which is formed in a silicon substrate. Other substrates that may be used include multi-layered substrates, gradient substrates, hybrid orientation substrates, the like, or a combination thereof. Other structures and/or configurations of the semiconductor layer 102 are within the scope of the present disclosure.

The patterned mask 104 may comprise a single layer, such as photoresist, or a plurality of individually formed layers that together form a mask stack. In some embodiments, the patterned mask 104 comprises at least one of a hard mask layer, a bottom antireflective coating (BARC) layer, an organic planarization layer (OPL), or a photoresist layer. The hard mask layer is formed by at least one of physical vapor deposition (PVD) (e.g., sputtering and/or evaporation), chemical vapor deposition (CVD) (e.g., low pressure CVD (LPCVD), ultrahigh vacuum CVD (UHVCVD), reduced pressure CVD (RPCVD), plasma-enhanced CVD (PECVD), and/or atmospheric pressure CVD (APCVD)), spin on, growth, or other suitable techniques. In some embodiments, the hard mask layer comprises at least one of silicon and oxygen, silicon and nitrogen, nitrogen, silicon (e.g., polycrystalline silicon), or other suitable materials. In some embodiments, the BARC layer is a polymer layer that is applied using a spin coating process. In some embodiments, the OPL comprises a photo-sensitive organic polymer that is applied using a spin coating process. In some embodiments, the OPL comprises a dielectric layer. In some embodiments, the photoresist layer is formed by at least one of spinning, spray coating, or other suitable techniques. The photoresist is a negative photoresist or a positive photoresist. With respect to a negative photoresist, regions of the negative photoresist become insoluble when illuminated by a light source, such that application of a solvent to the negative photoresist during a subsequent development stage removes non-illuminated regions of the negative photoresist. A pattern formed in the negative photoresist is thus a negative image of a pattern defined by opaque regions of a template, such as a mask, between the light source and the negative photoresist. In a positive photoresist, illuminated regions of the positive photoresist become soluble and are removed via application of a solvent during development. Thus, a pattern formed in the positive photoresist is a positive image of opaque regions of the template, such as a mask, between the light source and the positive photoresist. One or more etchants have a selectivity such that the one or more etchants remove or etch away one or more layers exposed or not covered by the photoresist at a greater rate than the one or more etchants remove or etch away the photoresist. Accordingly, an opening in the photoresist allows the one or more etchants to form a corresponding opening in the one or more layers under the photoresist, and thereby transfer a pattern in the photoresist to the one or more layers under the photoresist. The photoresist is stripped or washed away after the pattern transfer. The layers of the mask stack are patterned to form the patterned mask 104. In some embodiments, the photoresist layer is exposed using a radiation source and a reticle to define a pattern in the photoresist layer, and portions of the photoresist layer are removed to define a patterned photoresist layer. The underlying OPL, BARC layer, and hard mask layer are etched using the patterned photoresist layer as a template to form the patterned mask 104 and expose portions of the semiconductor layer 102 under the patterned mask 104. Other structures and configurations of the patterned mask 104 within the scope of the present disclosure.

Referring to FIG. 2, recesses 106 are formed in the semiconductor layer 102, in accordance with some embodiments. The recesses 106 may be formed by performing an etch process using the patterned mask 104 as an etch template. The etch process may be a timed etch process.

Referring to FIG. 3, the patterned mask 104 is removed and a bonding layer 108 is formed over the semiconductor layer 102, in accordance with some embodiments. The bonding layer 108 may comprise silicon dioxide. The bonding layer 108 provides an interface for bonding another semiconductor wafer.

Referring to FIG. 4, a semiconductor layer 110 is bonded to the bonding layer 108, in accordance with some embodiments. The semiconductor layer 110 does not fill the recesses 106. The semiconductor layer 110 may be provided as a separate semiconductor wafer or a die formed from a semiconductor wafer. The semiconductor layer 110 may include at least one of an epitaxial layer, a single crystalline semiconductor material such as, but not limited to at least one of Si, Ge, SiGe, InGaAs, GaAs, InSb, GaP, GaSb, InAlAs, GaSbP, GaAsSb, or InP. During the bonding process to attach the semiconductor layer 110 to the bonding layer 108, heat and/or pressure may be applied to the semiconductor layer 110 causing a bond to be formed between the semiconductor layer 110 and the bonding layer 108. Other substrates that may be used for the semiconductor layer 110 include multi-layered substrates, gradient substrates, hybrid orientation substrates, the like, or a combination thereof. Other structures and/or configurations of the semiconductor layer 110 are within the scope of the present disclosure.

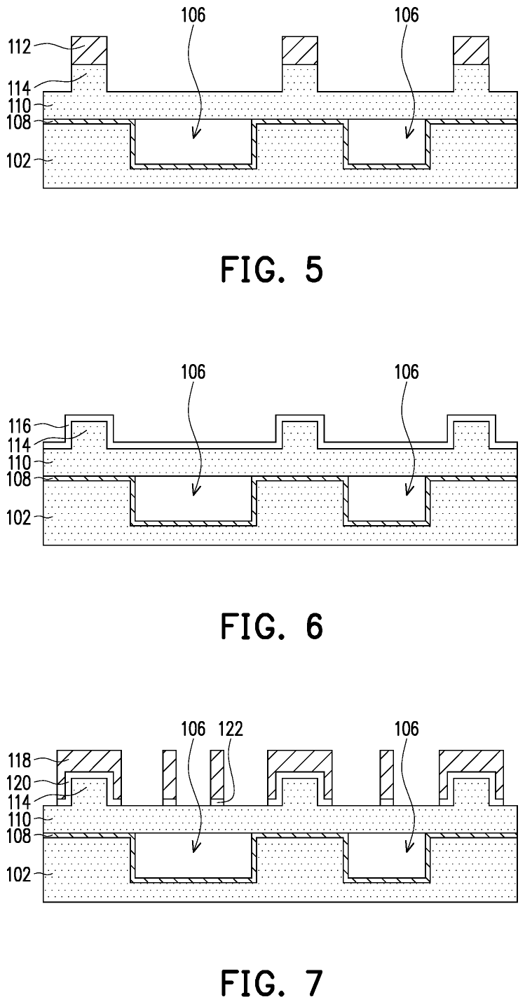

Referring to FIG. 5, a patterned mask 112 is formed over the semiconductor layer 110 and stand-off features 114 are formed in the semiconductor layer 110, in accordance with some embodiments. The patterned mask 112 may be a photoresist mask or a stack of mask layers including at least one of a hard mask layer, a BARC layer, an OPL, or a photoresist layer comprising materials and formed as described herein. The stand-off features 114 may be formed by performing an etch process using the patterned mask 112 as an etch template to remove portions of the semiconductor layer 110. The etch process may be a timed etch process. In some embodiments, the stand-off features 114 may have any closed shape when viewed from above such as a circular shape, a rectangular shape, or some other shape. The stand-off features 114 may define a bond ring for subsequent bonding of the MEMS structure to a device wafer.

Referring to FIG. 6, the patterned mask 112 is removed and a bond pad layer 116 is formed over the semiconductor layer 110 and the stand-off features 114, in accordance with some embodiments. In some embodiments, the bond pad layer 116 comprises germanium, a eutectic alloy of germanium, such as aluminum germanium (AlGe), or some other suitable material. A eutectic material is an alloy having a temperature where the constituents of the alloy melt at the same temperature and at a temperature lower than the melting point of any of its constituents. The bond pad layer 116 may be formed by using a sputtering process with a germanium or aluminum germanium target and an inert ion, such as argon, as the sputtering element.

Referring to FIG. 7, a patterned mask 118 is formed over the bond pad layer 116, and the bond pad layer 116 is patterned using the patterned mask 118 as a removal template to define first bond pads 120 from the bond pad layer 116 over the stand-off features 114 and to define second pads 122 from the bond pad layer 116 over portions of the semiconductor layer 110, in accordance with some embodiments. The patterned mask 118 may be a photoresist mask or a stack of mask layers including at least one of a hard mask layer, a BARC layer, an OPL, or a photoresist layer comprising materials and formed as described herein.

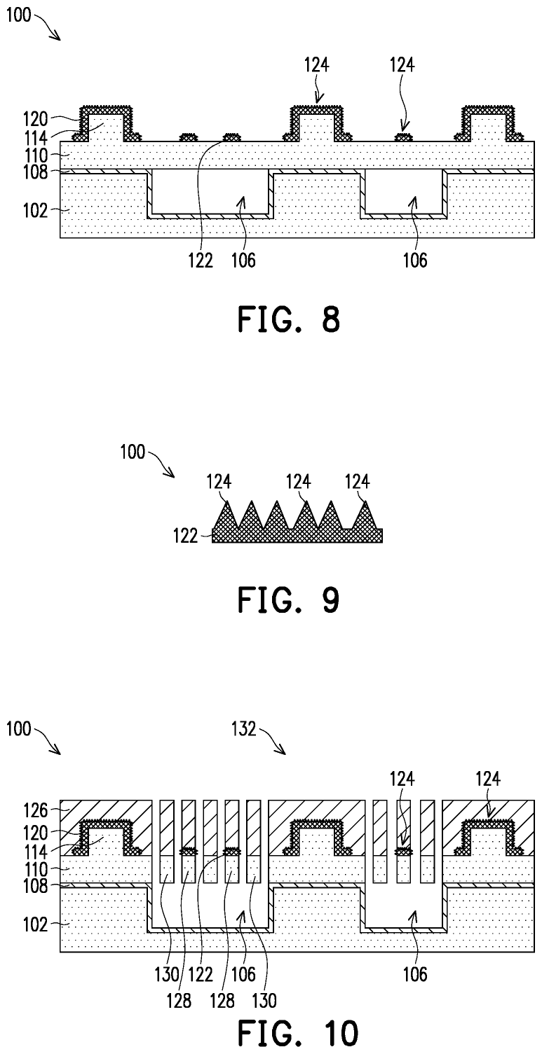

Referring to FIGS. 8 and 9, the patterned mask 118 is removed and an annealing process is performed to form anti-stiction bumps 124 on the first bond pads 120 and the second pads 122, in accordance with some embodiments. Referring to FIG. 9, an exploded view of one of the second pads 122 showing the anti-stiction bumps 124 is provided, in accordance with some embodiments. For illustration purposes, the size of the anti-stiction bumps 124 is exaggerated. The anti-stiction bumps 124 may be randomly distributed on the surfaces of the first bond pads 120 and the second pads 122. In some embodiments, the annealing process comprises a timed anneal in the presence of an inert gas, such as nitrogen, at a temperature of about 570° C. The annealing process causes crystallization of the material of the bond pad layer 116. In the case of materials including germanium, the crystallization resulting from the annealing process creates rough germanium with anti-stiction bumps 124 having a generally triangular vertical cross-sectional shape. The corners of the anti-stiction bumps 124 may be rounded. The horizontal cross-section shape of the anti-stiction bumps 124 may be a generally polygonal shape, such as a triangle, a trapezoid, a diamond, a pentagon, a hexagon, or some other shape. In some embodiments, the anti-stiction bumps 124 increase the surface roughness of the first bond pads 120 and the second pads 122. In some embodiments, the surface roughness is greater than about 20-30 nm with a wet contact angle of greater than about 20° compared to sputtered germanium that has a surface roughness of less than about 10 nm and a wet contact angle of less than about 10°.

Referring to FIG. 10 a patterned mask 126 is formed over the semiconductor layer 110, the first bond pads 120 over the stand-off features 114, the second pads 122, and the anti-stiction bumps 124, and the semiconductor layer 110 is patterned to form movable MEMS elements 128 and stationary MEMS elements 130 without removing the anti-stiction bumps 124, in accordance with some embodiments. The patterned mask 126 may be a photoresist mask or some other suitable mask stack that preserves the anti-stiction bumps 124 during the etch process and any processes to remove the patterned mask 126. In some embodiments, an etch process is performed in the presence of the patterned mask 126 to form the movable MEMS elements 128 and the stationary MEMS elements 130. The etch process may be a timed etch process. The anti-stiction bumps 124 remain at least on the uppermost horizontal surfaces of the first bond pads 120 over the stand-off features 114 and on the uppermost horizontal surfaces of the second pads 122 formed over the movable MEMS elements 128. The semiconductor layer 102, the stand-off features 114, the movable MEMS elements 128, and the stationary MEMS elements 130 define a MEMS structure 132.

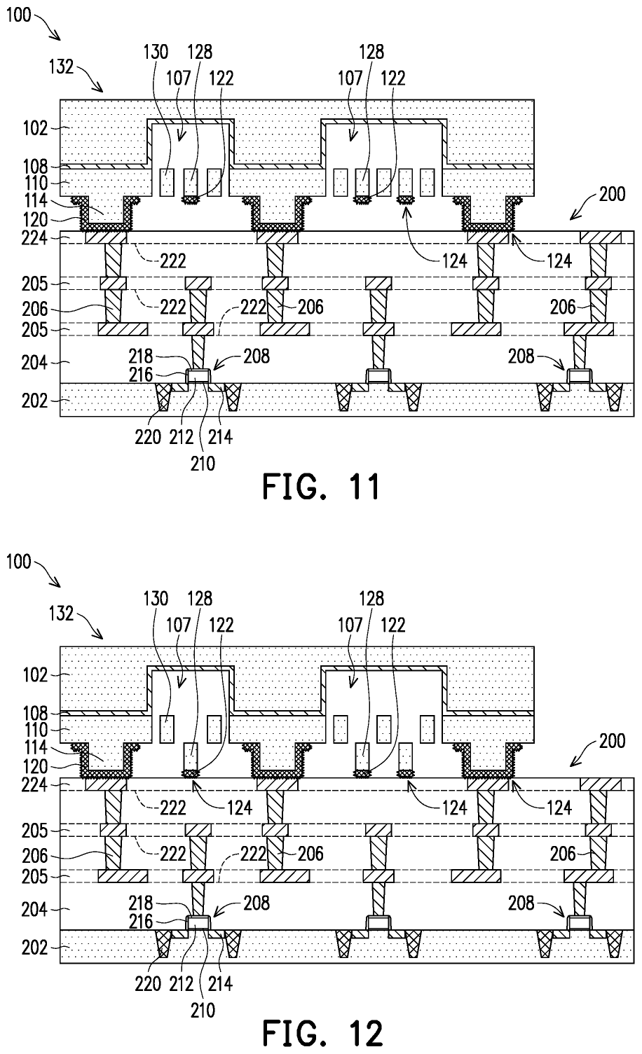

Referring to FIG. 11, the patterned mask 126 is removed, the MEMS structure 132 is inverted, and the MEMS structure 132 is bonded to a device die 200, in accordance with some embodiments. In some embodiments, heat and/or pressure is applied to bond the MEMS structure 132 to the device die 200. According to some embodiments, the device die 200 comprises a substrate layer 202, interlayer dielectric layers 204, 205, interconnect structures 206, an uppermost dielectric layer 224, and devices 208 formed over or within the substrate layer 202. Bonding the MEMS structure 132 to the device die 200 seals the recesses 106, thereby defining cavities 107 defined by the semiconductor layer 102, the bonding layer 108, the semiconductor layer 110, and the uppermost dielectric layer 224 that encapsulate the MEMS elements 128, 130. The device die 200 may be part of a semiconductor wafer that includes multiple device dies. At a later point in the production flow, the device wafer may be singulated to separate the device die 200 and the attached MEMS structure 132 into a single package.

In some embodiments, the devices 208 each comprise a gate dielectric layer 210 a gate electrode 212, source/drain regions 214, a sidewall spacer 216, a gate cap layer 218, etc. According to some embodiments, the gate dielectric layer 210, and the gate electrode 212 are formed using a gate replacement process. A sacrificial gate structure comprising a sacrificial gate dielectric layer, a sacrificial gate electrode layer, such as a polysilicon layer, and a hard mask layer are formed. In some embodiments, a patterning process is performed to pattern the hard mask layer corresponding to a pattern of gate structures to be formed, and an etch process is performed using the patterned hard mask layer to etch the sacrificial gate electrode layer and the sacrificial gate dielectric layer to define the sacrificial gate structure. In some embodiments, remaining portions of the hard mask layer form a cap layer over the portions of the sacrificial gate electrode layer remaining after the etch process. The sacrificial gate structure is later replaced with a replacement gate dielectric layer, such as the gate dielectric layer 210 and a replacement gate electrode, such as the gate electrode 212.

In some embodiments, the gate dielectric layer 210 comprises a high-k dielectric material. As used herein, the term “high-k dielectric” refers to the material having a dielectric constant, k, greater than or equal to about 3.9, which is the k value of SiO₂. The high-k dielectric material may be any suitable material. Examples of the high-k dielectric material include but are not limited to Al₂O₃, HfO₂, ZrO₂, La₂O₃, TiO₂, SrTiO₃, LaAlO₃, Y₂O₃, Al₂OₓN_{y}, HfOₓN_{y}, ZrOₓN_{y}, La₂OₓN_{y}, TiOₓN_{y}, SrTiOₓN_{y}, LaAlOₓN_{y}, Y₂OₓN_{y}, SiON, SiNₓ, a silicate thereof, and an alloy thereof. Each value of x is independently from 0.5 to 3, and each value of y is independently from 0 to 2. In some embodiments, the gate dielectric layer 210 comprises a native oxide layer formed by exposure of the substrate layer 202 to oxygen at various points in the process flow, causing the formation of silicon dioxide on exposed surfaces. In some embodiments, an additional layer of dielectric material, such as silicon dioxide, a high-k dielectric material, or other suitable material, is formed over the native oxide to form the gate dielectric layer 210.

In some embodiments, the gate electrode 212 comprises a barrier layer, one or more work function material layers, a seed layer, a metal fill layer, or other suitable layers. In some embodiments, the metal fill layer comprises tungsten, aluminum, copper, cobalt, or other suitable material. In some embodiments, the gate dielectric layer 210 and the one or more layers that comprise the gate electrode 212 are deposited by at least one of atomic layer deposition (ALD), PVD, CVD, LPCVD, PECVD, atomic layer CVD (ALCVD), UHVCVD, RPCVD, molecular beam epitaxy (MBE), or other suitable techniques. In some embodiments, the gate electrode 212 is recessed and the gate cap layer 218 is formed in the recess.

In some embodiments, the sidewall spacer 216 is formed adjacent the gate dielectric layer 210 and the gate electrode 212. In some embodiments, the sidewall spacer 216 is formed by depositing a spacer layer over the sacrificial gate structure and performing an anisotropic etch process to remove horizontal portions of the spacer layer. In some embodiments, the sidewall spacer 216 comprises silicon nitride or other suitable materials.

In some embodiments, the source/drain regions 214 are formed in the substrate layer 202 after forming the sacrificial gate structure. For example, in some embodiments, portions of the substrate layer 202 are doped through an implantation process to form the source/drain regions 214. In some embodiments, an etch process is performed to recess the substrate layer 202 adjacent the sidewall spacer 216, and an epitaxial growth process is performed to form the source/drain regions 214.

In an embodiment, one or more shallow trench isolation (STI) structures 220 are formed within the substrate layer 202. In some embodiments, the STI structures 220 are formed by forming at least one mask layer over the substrate layer 202. In some embodiments, the at least one mask layer comprises a layer of oxide material over the substrate layer 202 and a layer of nitride material over the layer of oxide material, and/or one or more other suitable layers. At least some of the at least one mask layer is removed to define an etch mask for use as a template to etch the substrate layer 202 to form trenches. A dielectric material is formed in the trenches to define the STI structures 220. In some embodiments, the STI structures 220 include multiple layers, such as an oxide liner, a nitride liner formed over the oxide liner, an oxide fill material formed over the nitride liner, and/or other suitable materials.

In some embodiments, a fill material, such as the oxide fill material, is formed using a high density (HDP) plasma process. The HDP process uses precursor gases comprising at least one of silane (SiH₄), oxygen, argon, or other suitable gases. The HDP process includes a deposition component, which forms material on surfaces defining the trench, and a sputtering component, which removes or relocates deposited material. A deposition-to-sputtering ratio depends on gas ratios employed during the deposition component. According to some embodiments, argon and oxygen act as sputtering sources, and the particular values of the gas ratios are determined based on an aspect ratio of the trench. After forming the fill material, an annealing process is performed to densify the fill material. In some embodiments, the STI structures 220 generate compressive stress.

Although the substrate layer 202 and the STI structures 220 are illustrated as having coplanar upper surfaces at an interface where the substrate layer 202 abuts the STI structures 220, the relative heights can vary. For example, the STI structures 220 can be recessed relative to the substrate layer 202 or the substrate layer 202 can be recessed relative to the STI structures 220. The relative heights at the interface depend on the processes performed for forming the STI structures 220, such as at least one of deposition, planarization, mask removal, surface treatment, or other suitable techniques. In some embodiments, the STI structures 220 are formed prior to forming the devices 208. Other structures and/or configurations of the STI structures 220 are within the scope of the present disclosure.

In some embodiments, the devices 208 are formed using the same materials and layer thicknesses. In some embodiments, different materials and/or thicknesses may be used due to the different voltage domains. For example, the material and/or thickness of the gate dielectric layers 210 may differ from one another. Although the devices 208 are illustrated as being adjacent one other, in some embodiments, the devices 208 are formed in different regions. For example, if the gate dielectric layers 210 vary in thickness or material, the differing devices 208 may be formed in different regions. In some embodiments, the materials of the gate electrode 212 may also differ. Other structures and configurations of the devices 208 are within the scope of the present disclosure. For example, the devices 208 may be fin field-effect transistor (finFET) devices, nanosheet devices, nanowire devices, or some other suitable type of device.

The interlayer dielectric layers 204, 205 are formed over the devices 208. In some embodiments, the interlayer dielectric layer 204 is formed prior to forming the replacement gate structures, if applicable. In some embodiments, the interlayer dielectric layers 204, 205 comprise silicon dioxide or a low-k dielectric material. In some embodiments, the interlayer dielectric layers 204, 205 comprises one or more layers of low-k dielectric material. Low-k dielectric materials have a k value lower than about 3.9. In some embodiments, the material for the interlayer dielectric layers 204, 205 comprise at least one of Si, O, C, or H, such as SiCOH, SiOC, oxygen-doped SiC (ODC), nitrogen-doped SiC (NDC), plasma-enhanced oxide (PEOX), or other suitable materials. A low-k dielectric material is, in some embodiments, further characterized or classified as ultra low-k (ULK), extra low-k (ELK), or extreme low-k (XLK), where the classification is generally based upon the k value. For example, ULK generally refers to materials with a k value of between about 2.7 to about 2.4, ELK generally refers to materials with a k value of between about 2.3 to about 2.0, and XLK generally refers to materials with a k value of less than about 2.0. Organic material, such as polymers, may be used for the interlayer dielectric layer 204. In some embodiments, the interlayer dielectric layer 204 comprises one or more layers of a carbon-containing material, organo-silicate glass, a porogen-containing material, or combinations thereof. The interlayer dielectric layer 204 comprises nitrogen in some embodiments. In some embodiments, the interlayer dielectric layer 204 is formed by using, for example, at least one of CVD, PECVD, LPCVD, ALCVD, a spin-on technology, or some other suitable process.

In some embodiments, the interlayer dielectric layers 205 and interconnect structures 206 form metallization layers to interconnect the devices 208 and to anchor the MEMS structure 132. The number of metallization layers may vary. The interconnect structures 206 may include via features. The interconnect structures 206 are formed in any number of ways, such as by a single damascene process, a dual damascene process, a trench silicide process, or some other suitable process. In some embodiments, the interconnect structures 206 contact the gate electrodes 212 and additional contacts (not shown) are formed to contact the source/drain regions 214 in different positions along the axial lengths of the devices 208, such as into or out of the page. In some embodiments, the interconnect structures 206 comprise a barrier layer, a seed layer, a metal fill layer, or other suitable layers. In some embodiments, the metal fill layer comprises tungsten, aluminum, copper, cobalt, or other suitable material. Any number of metallization layers are contemplated. In some embodiments, different metallization layers are separated by etch stop layers 222 to allow etch control for forming various interconnect structures 206 embedded in the interlayer dielectric layers 205. The etch stop layers 222 comprise a dielectric material having a different etch selectivity from the interlayer dielectric layers 205. In some embodiments, at least one of the etch stop layers 222 comprises SiN, SiCN, SiCO, CN, etc., alone or in combination. The etch stop layers 222 are formed in any number of ways, such as by thermal growth, chemical growth, ALD, CVD, PECVD, or some other suitable process.

In some embodiments, uppermost portions of the interconnect structures 206 comprise a eutectic material, such as AlCu, that bonds with the first bond pads 120 over the stand-off features 114. The uppermost dielectric layer 224 of the device die 200 may comprise a passivation oxide martial. During the bonding of the MEMS structure 132 to the device die 200, the large grain of the first bond pads 120 resulting from the anti-stiction bumps 124 helps break through the eutectic interface into the upper surface of the interconnect structures 206 positioned under the stand-off features 114 and improves the quality of the bond. In some embodiments, the increased bond quality allows a reduction in the pressure applied during the bonding process, reducing the likelihood or warping, damage, or wafer breakage.

Referring to FIG. 12, the movable MEMS elements 128 may move within the cavities 107 to perform the sensing function of the semiconductor structure 100. In some cases, the movable MEMS elements 128 may contact a surface of the uppermost dielectric layer 224. The increased surface roughness, such as a surface roughness of at least 20 nm, provided by the anti-stiction bumps 124 reduces the likelihood that one of the movable MEMS elements 128 will adhere to the uppermost dielectric layer 224 of the device die 200, thus reducing the possibility of damaging the sensing ability of the MEMS structure 132. The same photomask is used to form the second pads 122 on which the anti-stiction bumps 124 are formed and to form the first bond pads 120 over the stand-off features 114. An annealing process may be used to crystalize the material of the bond pad layer 116 to form the anti-stiction bumps 124. The simple process flow reduces process complexity and cost, thereby increasing throughput and profitability.

In some embodiments, the devices 208 are portions of a circuit implemented by the semiconductor structure 100 for sensing using the MEMS structure 132. The circuit may comprises a sensor circuit comprising at least one of an image sensor, a complementary metal-oxide-semiconductor (CMOS) image sensor (CIS), a backside CIS, a proximity sensor, a time of flight (ToF) sensor, an indirect ToF (iToF) sensor, a backside illumination (BSI) sensor, or some other type of sensor. In some embodiments, the circuit comprises a logic circuit, a light-emitting diode (LED) circuit, a liquid-crystal display (LCD) circuit, a random access memory (RAM) circuit, or other type of circuit. Other structures and/or configurations of the semiconductor structure 100 are within the scope of the present disclosure.

In some embodiments, a semiconductor structure is provided. The semiconductor structure includes a first semiconductor layer, a micro-electromechanical systems (MEMS) structure defined in the first semiconductor layer, and a first dielectric layer bonded to the first semiconductor layer. The MEMS structure has a first surface comprises a first pad. The first dielectric layer has a second surface facing the first surface. First anti-stiction bumps are on the first pad.

In some embodiments, a semiconductor structure is provided. The semiconductor structure includes a micro-electromechanical systems (MEMS) structure including a movable element, and a stand-off feature. A device die is bonded to the stand-off feature. The movable element is movable within a cavity defined by the MEMS structure and the device die. The movable element has a first surface comprises a first pad. The device die has a second surface facing the first surface of the movable element. A surface roughness of the first pad is at least 20 nm.

In some embodiments, a method for forming a semiconductor structure is provided. The method includes forming a first semiconductor layer including a stand-off feature. A bond pad layer is formed over the first semiconductor layer and the stand-off feature. The bond pad layer is patterned to form a first bond pad over the stand-off feature and a second pad over a portion of the first semiconductor layer. An annealing process is performed to increase a surface roughness of the first bond pad and the second pad. The first semiconductor layer is patterned to form a micro-electromechanical systems (MEMS) structure including a movable element. A device die is bonded to the stand-off feature. The second pad is over the movable element.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

Although the subject matter has been described in language specific to structural features or methodological acts, it is to be understood that the subject matter of the appended claims is not necessarily limited to the specific features or acts described above. Rather, the specific features and acts described above are disclosed as example forms of implementing at least some of the claims.

Various operations of embodiments are provided herein. The order in which some or all of the operations are described should not be construed to imply that these operations are necessarily order dependent. Alternative ordering will be appreciated having the benefit of this description. Further, it will be understood that not all operations are necessarily present in each embodiment provided herein. Also, it will be understood that not all operations are necessary in some embodiments.

It will be appreciated that layers, features, elements, etc. depicted herein are illustrated with particular dimensions relative to one another, such as structural dimensions or orientations, for example, for purposes of simplicity and ease of understanding and that actual dimensions of the same differ substantially from that illustrated herein, in some embodiments. Additionally, a variety of techniques exist for forming the layers, regions, features, elements, etc. mentioned herein, such as at least one of etching techniques, planarization techniques, implanting techniques, doping techniques, spin-on techniques, sputtering techniques, growth techniques, or deposition techniques such as chemical vapor deposition (CVD), for example.

Moreover, “exemplary” is used herein to mean serving as an example, instance, illustration, etc., and not necessarily as advantageous. As used in this application, “or” is intended to mean an inclusive “or” rather than an exclusive “or”. In addition, “a” and “an” as used in this application and the appended claims are generally be construed to mean “one or more” unless specified otherwise or clear from context to be directed to a singular form. Also, at least one of A and B and/or the like generally means A or B or both A and B. Furthermore, to the extent that “includes”, “having”, “has”, “with”, or variants thereof are used, such terms are intended to be inclusive in a manner similar to the term “comprising”. Also, unless specified otherwise, “first,” “second,” or the like are not intended to imply a temporal aspect, a spatial aspect, an ordering, etc. Rather, such terms are merely used as identifiers, names, etc. for features, elements, items, etc. For example, a first element and a second element generally correspond to element A and element B or two different or two identical elements or the same element.

Also, although the disclosure has been shown and described with respect to one or more implementations, equivalent alterations and modifications will occur to others of ordinary skill in the art based upon a reading and understanding of this specification and the annexed drawings. The disclosure comprises all such modifications and alterations and is limited only by the scope of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure. In addition, while a particular feature of the disclosure may have been disclosed with respect to only one of several implementations, such feature may be combined with one or more other features of the other implementations as may be desired and advantageous for any given or particular application.

What is claimed is:

1. A semiconductor structure, comprising:
a first semiconductor layer;
a micro-electromechanical systems (MEMS) structure defined in the first semiconductor layer; and
a first dielectric layer bonded to the first semiconductor layer, wherein:
the MEMS structure has a first surface comprising a first pad;
the first dielectric layer has a second surface facing the first surface; and
first anti-stiction bumps are on the first pad.

2. The semiconductor structure of claim 1, comprising:
a second semiconductor layer defining a recess;
a stand-off feature defined in the first semiconductor layer, and
a bonding layer over the second semiconductor layer and bonded to the stand-off feature, wherein:
the second semiconductor layer closes the recess to define a cavity; and
the MEMS structure comprises movable elements movable within the cavity.

3. The semiconductor structure of claim 1, comprising:
an interconnect structure embedded in the first dielectric layer;
a stand-off feature in the first semiconductor layer; and
a second bond pad over the stand-off feature, wherein the second bond pad is bonded to the interconnect structure.

4. The semiconductor structure of claim 3, comprising:
second anti-stiction bumps on the second bond pad.

5. The semiconductor structure of claim 1, wherein:
the first anti-stiction bumps comprise germanium.

6. The semiconductor structure of claim 1, wherein:
the first anti-stiction bumps have a triangular vertical cross section.

7. The semiconductor structure of claim 1, wherein:
a surface roughness of the first pad is at least about 20 nm.

8. A semiconductor structure, comprising:
a micro-electromechanical systems (MEMS) structure, comprising:
a movable element; and
a stand-off feature; and
a device die bonded to the stand-off feature, wherein:
the movable element is movable within a cavity defined by the MEMS structure and the device die.
the movable element has a first surface comprising a first pad;
the device die has a second surface facing the first surface of the movable element; and
a surface roughness of the first pad is at least 20 nm.

9. The semiconductor structure of claim 8, wherein:
the first pad comprises germanium.

10. The semiconductor structure of claim 8, wherein:
the first pad comprises first anti-stiction bumps.

11. The semiconductor structure of claim 10, wherein:
the first anti-stiction bumps have a triangular vertical cross section.

12. The semiconductor structure of claim 10, comprising:
a second bond pad over the stand-off feature, wherein:
the device die comprises an interconnect structure bonded to the second bond pad, and
the second bond pad comprises second anti-stiction bumps.

13. The semiconductor structure of claim 12, wherein:
the interconnect structure comprises a eutectic material comprising copper.

14. The semiconductor structure of claim 12, wherein:
the second bond pad comprises germanium.

15. A method for forming a semiconductor structure, comprising:
forming a first semiconductor layer comprising a stand-off feature;
forming a bond pad layer over the first semiconductor layer and the stand-off feature;
patterning the bond pad layer to form a first bond pad over the stand-off feature and a second pad over a portion of the first semiconductor layer;
performing an annealing process to increase a surface roughness of the first bond pad and the second pad;
patterning the first semiconductor layer to form a micro-electromechanical systems (MEMS) structure comprising a movable element; and
bonding a device die to the stand-off feature, wherein the second pad is over the movable element.

16. The method of claim 15, wherein:
performing the annealing process forms first anti-stiction bumps on the first bond pad and second anti-stiction bumps on the second pad.

17. The method of claim 15, wherein:
forming the bond pad layer comprises forming the bond pad layer comprising germanium.

18. The method of claim 15, wherein performing the annealing process comprises performing the annealing process to increase the surface roughness of the first bond pad and the second pad to at least 20 nm.

19. The method of claim 15, wherein:
the device die comprises an interconnect structure; and
bonding the device die to the stand-off feature comprises bonding the stand-off feature to the interconnect structure.

20. The method of claim 19, wherein:
the interconnect structure comprises a eutectic material comprising copper; and
bonding the device die to the stand-off feature comprises bonding the stand-off feature to the eutectic material.
